(19) United States
(12) Patent Application Publication
(10) Pub. No.: US 2014/0273432 A1
(43) Pub. Date: Sep. 18, 2014

(54) FABRICATING METHOD OF SEMICONDUCTOR DEVICE

(71) Applicants: BYUNG-HEE KIM, Seoul (KR); Tae-Soo Kim, Seoul (KR); Seong-Ho Park, Hwaseong-si (KR); Young-Ju Park, Seoul (KR); Ju-Young Jung, Fishkill, NY (US)

(72) Inventors: BYUNG-HEE KIM, Seoul (KR); Tae-Soo Kim, Seoul (KR); Seong-Ho Park, Hwaseong-si (KR); Young-Ju Park, Seoul (KR); Ju-Young Jung, Fishkill, NY (US)

(21) Appl. No.: 13/841,132

(22) Filed: Mar. 15, 2013

(51) Int. Cl. H01L 21/768

(52) U.S. Cl. CPC H01L 21/76805
USPC 438/631

(57) ABSTRACT

A semiconductor device is fabricated by forming a lower conductor in a first interlayer dielectric film. A second interlayer dielectric film is formed on the lower conductor and the first interlayer dielectric film. A first hard mask pattern is formed on the second interlayer dielectric film. The first mask pattern has a first opening extending in a first direction. A planarization layer is formed on the first hard mask pattern. A mask pattern is formed on the planarization layer. The mask pattern has a second opening extending in a second direction perpendicular to the first direction. The lower conductor is positioned under an region where the first opening and the second opening overlap. A via hole and a trench connected to the via hole is formed using the first hard mask pattern and the mask pattern. The via hole exposes an upper surface of the lower conductor.

### TECHNICAL FIELD

The present inventive concept relates to a fabricating method of a semiconductor device.

### DISCUSSION OF RELATED ART

Semiconductor devices have multi-level interconnection structures having a via electrically connecting a lower conductor and an upper conductor. As semiconductor devices gradually scale down, sizes of lower conductors, upper conductors, vias, etc. are decreasing and a distance between neighboring conductors is gradually becoming reduced.

### SUMMARY

According to an exemplary embodiment of the present inventive concept, a semiconductor device is fabricated by forming a lower conductor in a first interlayer dielectric film. A second interlayer dielectric film is formed on the lower conductor and the first interlayer dielectric film. A first hard mask pattern is formed on the second interlayer dielectric film. The first hard mask pattern has a first opening. A planarization layer is formed on the first hard mask pattern. A mask layer is formed on the planarization layer. A second hard mask pattern, having a second opening, is formed on the mask layer. The second hard mask pattern includes SiN. A mask pattern is formed by patterning the mask layer using the second hard mask pattern. The second hard mask pattern is removed. Trenches and via holes are formed in the second interlayer dielectric film using the mask pattern and the first hard mask pattern.

According to an exemplary embodiment of the present inventive concept, a semiconductor device is fabricated by forming a lower conductor in a first interlayer dielectric film. A second interlayer dielectric film is formed on the lower conductor and the first interlayer dielectric film. A first hard mask pattern is formed on the second interlayer dielectric film. The first hard mask pattern includes a metal layer. The first hard mask pattern includes a first opening extending in a first direction. A planarization layer is formed on the first hard mask pattern. A mask layer is formed on the planarization layer. A second hard mask pattern is formed on the mask layer. The second hard mask pattern includes SiN. The second mask pattern has a second opening extending in a second direction different from the first direction. A mask pattern is formed by patterning the mask layer using the second hard mask pattern. The second hard mask pattern is removed by using a wet process. Trenches and via holes are formed in the second interlayer dielectric film using the mask pattern and the first hard mask pattern.

According to an exemplary embodiment of the present inventive concept, a semiconductor device is fabricated by forming a lower conductor in a first interlayer dielectric film. A second interlayer dielectric film is formed on the lower conductor and the first interlayer dielectric film. A first hard mask pattern is formed on the second interlayer dielectric film. The first mask pattern has a first opening extending in a first direction. A planarization layer is formed on the first hard mask pattern. A mask pattern is formed on the planarization layer. The mask pattern has a second opening extending in a second direction perpendicular to the first direction. The lower conductor is positioned under a region where the first opening and the second opening overlap. A via hole and a trench connected to the via hole is formed using the first hard mask pattern and the mask pattern. The via hole exposes an upper surface of the lower conductor.

### BRIEF DESCRIPTION OF THE DRAWINGS

These and other features of the inventive concept will become more apparent by describing in detail exemplary embodiments thereof with reference to the accompanying drawings of which:

FIGS. 1 to 12 show intermediate process steps in a fabricating method of a semiconductor device according to an embodiment of the present inventive concept;

FIG. 13 is a block diagram of an electronic system incorporating a semiconductor device fabricated by the method shown in FIGS. 1 to 12; and

FIGS. 14 and 15 show an exemplary semiconductor system that includes an semiconductor device fabricated by an exemplary embodiment.

### DETAILED DESCRIPTION OF THE EMBODIMENTS

Exemplary embodiments of the inventive concept will be described below in more detail with reference to the accompanying drawings. However, the inventive concept may be embodied in different forms and should not be construed as limited to the embodiments set forth herein. Rather, these exemplary embodiments are provided so that this disclosure will be thorough and complete and will fully convey the inventive concept to those skilled in the art. In the drawings, the thickness of layers and regions may be exaggerated for clarity. Like reference numerals may refer to the like elements throughout the specification and drawings.

Hereinafter, a fabricating method of a semiconductor device according to an exemplary embodiment of the present inventive concept will now be described with reference to FIGS. 1 to 12. FIGS. 1 to 12 illustrate intermediate process steps in a fabricating method of a semiconductor device according to an exemplary embodiment of the present inventive concept. Specifically, FIG. 2 is a cross-sectional view taken along the line X-X of FIG. 1, FIG. 4 is a cross-sectional view taken along the line X-X of FIG. 3, FIG. 6 is a cross-sectional view taken along the line X-X of FIG. 5, and FIG. 12 is a perspective view illustrating interconnections and vias.

Referring to FIGS. 1 and 2, lower conductors 171 to 175 are formed on a substrate and a first interlayer dielectric film 180 is formed around the lower conductors 171 to 175.

For example, the lower conductors 171 to 175 may be contacts or interconnections, but the present inventive concept is not limited thereto. As shown in FIGS. 1 and 2, the lower conductors 171 to 175 may be island-shaped or may be formed to extend in a direction. The lower conductors 171 to 175 may include, for example, aluminum or tungsten, but the present inventive concept is not limited thereto.

A bather layer (not shown) may be formed along the sidewalls and bottom surface of the lower conductors 171 to 175. The barrier layer may include, for example, Ti and/or TiN. The barrier layer may be a stacked layer of Ti/TiN. The lower conductors 171 to 175 may be spaced apart from each other in a second direction D2.

The first interlayer dielectric film 180 may include SiO₂, SiN, SiON, SiCN, and/or a low dielectric constant (low-k) material, but the present inventive concept is not limited thereto.

An insulation layer 190 and a second interlayer dielectric film 195 may be formed on the lower conductors 171 to 175 and the first interlayer dielectric film 180. For example, the insulation layer 190 may include SiCN and have a dielectric constant of approximately 4.5. The second interlayer dielectric film 195 may include a low-k dielectric material, but the present inventive concept is not limited thereto.

Insulation layers 302 and 303 may be formed on the second interlayer dielectric film 195. The insulation layer 302 may include, for example, octamethylcyclotetrasiloxane (OMCTS) having a dielectric constant of approximately 2.7, but the present inventive concept is not limited thereto. The insulation layer 303 may include tetraethoxysilane (TEOS) SiO₂, but the present inventive concept is not limited thereto.

The insulation layers 302 and 303 may serve to protect the second interlayer dielectric film 195 from plasma damages that may occur in a subsequent process of forming a metallic hard mask pattern 305.

Referring to FIGS. 3 and 4, a first hard mask pattern 301 having first openings 311 to 315 is formed on the insulation layers 302 and 303.

For example, the first hard mask pattern 301 may include a metallic hard mask pattern 305 and an insulating hard mask pattern 307. For example, the metallic hard mask pattern 305 may include TiN, Ta and/or TaN. The insulating hard mask pattern 307 may include SiO₂, SiN, SiON, and/or SiCN. For example, the first hard mask pattern 301 may include the metallic hard mask pattern 305 having TiN and the insulating hard mask pattern 307 having TEOS SiO₂, but the inventive concept is not limited thereto.

The metallic hard mask pattern 305 has high etch selectivity with respect to the second interlayer dielectric film 195. For example, the etch selectivity of the metallic hard mask pattern 305 to the second interlayer dielectric film 195 may be 1:20 or higher.

The metallic hard mask pattern 305 may serve to maintain/adjust widths of via holes (296 to 299 of FIG. 11) and trenches (291 to 294 of FIG. 11)

The insulating hard mask pattern 307 may serve to reduce etch by-products of metallic polymers that are generated from the metallic hard mask pattern 305 in etching the second interlayer dielectric film 195 using the first hard mask pattern. The insulating hard mask pattern 307 covers the metallic hard mask pattern 305, and the formation of the metallic polymers may be reduced. If the metallic hard mask pattern 305 is used alone without using the insulating hard mask pattern 307 in etching the second interlayer dielectric film 195, metallic polymers may be generated formed from the metallic hard mask pattern 305 and may be deposited around the via holes 296 to 299. It is difficult to remove the deposited metallic polymers.

The insulating hard mask pattern 307, covering the metallic hard mask pattern 305, reduces the metallic polymers deposited on the via holes 296 to 299, thereby improving bottom profiles of the via holes 296 to 299.

For example, the insulating hard mask pattern 307 may have a thickness in a range of 350 Å to 450 Å and the metallic hard mask pattern 305 may have a thickness in a range of 250 Å to 350 Å, but the present inventive concept is not limited thereto. The thickness of the metallic hard mask pattern 305 may be reduced using the insulating hard mask pattern 307.

The first openings 311 to 315 may be formed to extend in the first direction D1. The first openings 311 to 315 may be arranged to be adjacent to each other in the second direction D2.

Referring to FIGS. 5 and 6, a planarization layer 350 and a mask layer 360a are sequentially formed on the resulting structure of FIG. 4.

The planarization layer 350 may include, for example, an optical planarization layer (OPL), but the present inventive concept is not limited thereto. The planarization layer 350 may have a thickness to sufficiently fill the first openings 311 to 315 and may cover the first hard mask pattern 301. The mask layer 360a and a second hard mask pattern 370 are formed on the planarization layer 350. The mask layer 360a may include, for example, low temperature oxide (LTO), but the present inventive concept is not limited thereto.

Next, a second hard mask pattern 370 having a second opening 371 is formed on the mask layer 360a.

The second hard mask pattern 370 may be used when the mask layer 360a is etched.

The second hard mask pattern 370 may include SiNCₓO_{y} (where, 0≦x≦1, and x+y=1). Since SiNCₓO_{y} transmits light, an alignment signal is well transmitted in a lithography process. Therefore; misalignment may be reduced, thereby increasing process accuracy. The second hard mask pattern 370 does not include a metal that may scatter the alignment signal. Such scattering may lower the process accuracy in a lithography process.

The first hard mask pattern 301 and the second hard mask pattern 370 may include different materials. As described above, the first hard mask pattern 301 may include a stacked layer of TiN and TEOS SiO₂, and the second hard mask pattern 370 may include SiNCₓO_{y}.

The second opening 371 may be formed to extend in the second direction D2 different from the first direction D1. In FIG. 5, the first direction D1 and the second direction D2 are disposed at right angle, but the present inventive concept is not limited thereto. The second opening 371 is formed to overlap part of the first openings 311 to 315. For example, the second opening 371 overlaps the first openings 312 to 315, but the present inventive concept is not limited thereto. As shown in FIG. 5, the lower conductors 172 to 175 are positioned under corresponding overlapped regions that the first openings 312 to 315 and the second opening 371 overlap. The vias (161 to 164 of FIG. 11) are also positioned under the corresponding overlapped regions between the first openings 312 to 315 and the second opening 371. The vias 161 to 164 of FIG. 11 contact the lower conductors 172 to 175.

Referring to FIG. 7, a mask pattern 360 is formed by patterning the mask layer 360a using the second hard mask pattern 370.

Referring to FIG. 8, the second hard mask pattern 370 is removed.

For example, when the second hard mask pattern 370 includes SiNCₓP_{y}, it may be removed using a wet process. For example, the second hard mask pattern 370 may be removed by performing a stripping process using a phosphoric acid solution.

The second hard mask pattern 370 does not include a metal. If the second hard mask pattern 370 includes a metal, a reactive ion etching (RIE) process may generate a metal residue, and this metal residue may hinder the second hard mask pattern 370 from completely being removed.

Referring to FIGS. 9 and 10, the trenches 291 to 294 and the via holes 296 to 299 are formed in the second interlayer dielectric film 195 using the mask pattern 360 and the first hard mask pattern 301.

For example, referring to FIG. 9, preliminary via holes 296a to 299a are formed in the second interlayer dielectric film 195 using the mask pattern 360 and the first hard mask pattern 301.

The preliminary via holes 296a to 299a are formed by selectively etching the second interlayer dielectric film 195 to a predetermined depth and stopping the etching process before a top surface of the insulation layer 190 is exposed. The preliminary via holes 296a to 299a may be formed using, for example, a dry etching process.

Referring to FIG. 10, the mask pattern 360 and the planarization layer 350 are removed.

Next, the second interlayer dielectric film 195 having the preliminary via holes 296a to 299a is further etched to form via holes 296 to 299 that expose corresponding upper surfaces of the lower conductors 171 to 175 using the first hard mask pattern 301 and the preliminary via holes 296a to 299a. While the trenches 291 to 294 are formed using the first hard mask pattern 301, the via holes 296 to 299 are simultaneously formed using the preliminary via holes 296a to 299a.

The via holes 296 to 299 and trenches 291 to 294 may be formed using, for example, a dry etching process. According to an exemplary embodiment, the insulating hard mask pattern 307 may have a predetermined thickness completely removed by the dry etching process, and the metallic hard mask pattern 305 may be partially removed.

Referring to FIGS. 11 and 12, the interconnections 165 to 169 and the vias 161 to 164 are formed in the via holes 296 to 299 and the trenches 291 to 294.

For example, a conductive material (not shown) is formed in the via holes 296 to 299 and the trenches 291 to 294 to sufficiently fill the via holes 296 to 299 and the trenches 291 to 294. The conductive material may be, for example, copper, but the present inventive concept is not limited thereto. Next, a planarization process (e.g., a chemical mechanical polishing (CMP) process) is performed to remove the conductive material except in the via holes 296 to 299 and the trenches 291 and 294, thereby forming the interconnections 165 to 169 and the vias 161 to 164 in the trenches 291 to 295 and the via holes 296 to 299, respectively.

FIG. 13 is a block diagram of an electronic system incorporating a semiconductor device fabricated according to an embodiment of the inventive concept.

Referring to FIG. 13, the electronic system 1100 may include a controller 1110, an input/output (I/O) device 1120, a memory device 1130, an interface 1140 and a bus 1150. The controller 1110, the I/O device 1120, the memory device 1130 and/or the interface 1140 may be connected to each other through the bus 1150. The bus 1150 may corresponds to a path through which data is transmitted.

The controller 1110 may include a microprocessor, a digital signal processor, a microcontroller, and/or logic devices. For example, the logic device may perform similar functions to those performed by the processor or microcontroller. The I/O device 1120 may include a keypad, a keyboard, and/or a display device. The memory device 1130 may store data and/or instructions. The interface 1140 may transmit/receive data to/from a communication network. The interface 1140 may be wired or wireless. For example, the interface 1140 may include an antenna or a wired/wireless transceiver. The electronic system 1100 may be used as an operating memory (not shown) for improving the operation of the controller 1110 and may further include a high-speed DRAM and/or SRAM. The fin-type transistor according to embodiments of the present inventive concept may be provided within the memory device 1130 or may be provided as a component of the controller 1110 or the I/O device 1120.

The electronic system 1100 may be applied to a personal digital assistant (PDA), a portable computer, a web tablet, a wireless phone, a mobile phone, a digital music player, a memory card, or any type of electronic device capable of transmitting and/or receiving information in a wireless environment.

FIGS. 14 and 15 illustrate an exemplary semiconductor system to which a semiconductor device fabricated according to an embodiment of the inventive concept. For example, FIGS. 14 and 15, respectively, illustrate a tablet PC and a notebook computer including semiconductor devices according to embodiments of the present inventive concept. The application is not limited to the above, but any electronic system may include semiconductor devices according to embodiments of the present inventive concept. While the present inventive concept has been shown and described with reference to exemplary embodiments thereof, it will be apparent to those of ordinary skill in the art that various changes in form and detail may be made therein without departing from the sprit and scope of the inventive concept as defined by the following claims.

What is claimed is:

1. A fabricating method of a semiconductor device comprising:
forming a lower conductor in a first interlayer dielectric film;
forming a second interlayer dielectric film on the lower conductor and the first interlayer dielectric film;
forming a first hard mask pattern on the second interlayer dielectric film, the first hard mask pattern having a first opening;
forming a planarization layer on the first hard mask pattern;
forming a mask layer on the planarization layer;
forming a second hard mask pattern having a second opening on the mask layer, the second hard mask pattern including SiN;
forming a mask pattern by patterning the mask layer using the second hard mask pattern;
removing the second hard mask pattern, and
forming trenches and via holes in the second interlayer dielectric film using the mask pattern and the first hard mask pattern.

2. The fabricating method of claim 1, wherein the second hard mask pattern is removed by using a wet process.

3. The fabricating method of claim 2, wherein the wet process includes a stripping process using a phosphoric acid solution.

4. The fabricating method of claim 1, wherein the first hard mask pattern and the second hard mask pattern include different materials.

5. The fabricating method of claim 4, wherein the first hard mask pattern includes a metallic hard mask pattern and an insulating hard mask pattern.

6. The fabricating method of claim 5, wherein the first hard mask pattern includes a TIN pattern and a TEOS SiO₂ pattern sequentially stacked.

7. The fabricating method of claim 1, wherein the mask layer includes low temperature oxide (LTO).

8. The fabricating method of claim 1, wherein the first opening is extended in a first direction and the second opening is extended in a second direction different from the first direction.

9. The fabricating method of claim 8, wherein the lower conductor is positioned under a region where the first opening and the second opening overlaps.

10. The fabricating method of claim 1, wherein the forming of the trenches and the via holes comprises:
forming preliminary via holes in the second interlayer dielectric film using the mask pattern and the first hard mask pattern, wherein the preliminary via holes are positioned under the region where the first opening and the second opening overlap;
removing the mask pattern and the planarization layer; and
forming via holes from the preliminary via holes exposing an upper surface of the lower conductor using the first hard mask pattern and forming the trenches connected to the via holes.

11. A fabricating method of a semiconductor device comprising:
forming a lower conductor in a first interlayer dielectric film;
forming a second interlayer dielectric film on the lower conductor and the first interlayer dielectric film;
forming a first hard mask pattern having a first opening extending in a first direction on the second interlayer dielectric film, the first hard mask pattern including a metal layer;
forming a planarization layer on the first hard mask pattern;
forming a mask layer on the planarization layer;
forming a second hard mask pattern on the mask layer, the second hard mask pattern including SiN, and having a second opening extending in a second direction different from the first direction;
forming a mask pattern by patterning the mask layer using the second hard mask pattern;
removing the second hard mask pattern using a wet process; and
forming trenches and via holes in the second interlayer dielectric film using the mask pattern and the first hard mask pattern.

12. The fabricating method of claim 11, wherein the removing of the second hard mask pattern comprises performing a stripping process using a phosphoric acid solution.

13. The fabricating method of claim 11, wherein the first hard mask pattern includes a TiN pattern and a TEOS SiO₂ pattern sequentially stacked.

14. The fabricating method of claim 11, wherein the mask layer includes low temperature oxide (LTO).

15. The fabricating method of claim 11, wherein the forming of the trenches and the via holes comprises:
forming a preliminary via hole in the second interlayer dielectric film using the mask pattern and the first hard mask pattern;
removing the mask pattern and the planarization layer; and
forming via holes from the preliminary via holes contacting the lower conductor using the first hard mask pattern and forming the trenches connected to the via holes.

16. A fabricating method of a semiconductor device comprising:
forming a lower conductor in a first interlayer dielectric film;
forming a second interlayer dielectric film on the lower conductor and the first interlayer dielectric film;
forming a first hard mask pattern on the second interlayer dielectric film, the first mask pattern having a first opening extending in a first direction;
forming a planarization layer on the first hard mask pattern;
forming a mask pattern on the planarization layer, the mask pattern having a second opening extending in a second direction perpendicular to the first direction, wherein the lower conductor is positioned under a region where the first opening and the second opening overlap; and
forming a via hole and a trench connected to the via hole using the first hard mask pattern and the mask pattern, wherein the via hole exposes an upper surface of the lower conductor,
wherein the mask pattern is formed using a second hard mask pattern including SiN.

17. The fabricating method of claim 16, wherein the forming the via hole and the trench comprises:
etching the planarization layer and the second interlayer dielectric film using the first hard mask pattern and the mask pattern, thereby forming a preliminary via hole under the region;
removing the mask pattern and the planarization layer; and
etching the second interlayer dielectric film having the preliminary via hole using the first hard mask pattern, thereby forming a trench and a via hole, wherein the trench is defined by the first hard mask pattern and the via hole is formed by the preliminary via hole extending vertically.

18. The fabricating method of claim 16, wherein the first hard mask pattern and the second hard mask pattern include different materials.

19. The fabricating method of claim 18, wherein the first hard mask pattern includes a metallic hard mask pattern and an insulating hard mask pattern, wherein the metallic hard mask pattern is formed on the second interlayer dielectric film and the insulating hard mask pattern is formed on the metallic hard mask pattern.

20. The fabricating method of claim 19, wherein the metallic hard mask includes a TiN, Ta or TaN, and the insulating hard mask pattern includes SiO₂, SiN, SiON, or SiCN.
